(19) United States
(12) Patent Application Publication
(10) Pub. No.: US 2013/0107451 A1
(43) Pub. Date: May 2, 2013

(54) SERVER SYSTEM WITH AIR COOLING DEVICE

(71) Applicant: Chao-Ke WEI, Tu-Cheng (TW)

(72) Inventor: Chao-Ke WEI, Tu-Cheng (TW)

(73) Assignee: HON HAI PRECISION INDUSTRY CO., LTD., Tu-Cheng (TW)

(21) Appl. No.: 13/326,250

(22) Filed: Dec. 14, 2011

(30) Foreign Application Priority Data
Oct. 27, 2011 (TW) 100139231

(51) Int. Cl. H05K 7/20

(52) U.S. Cl. 361/692

(57) ABSTRACT

A server system including a rack and an air cooling device is provided. The rack includes a plurality of support plates dividing the rack into a first chamber and a second chamber. A gap exists between each two adjacent support plates, communicating with the first chamber and the second chamber. The air cooling device includes a first unit defining a first inlet communicating with the first chamber and a first outlet communicating with the second chamber. The first unit cools the air taken from the first chamber via the first inlet, and outputs the cooled air into the second chamber via the first outlet.

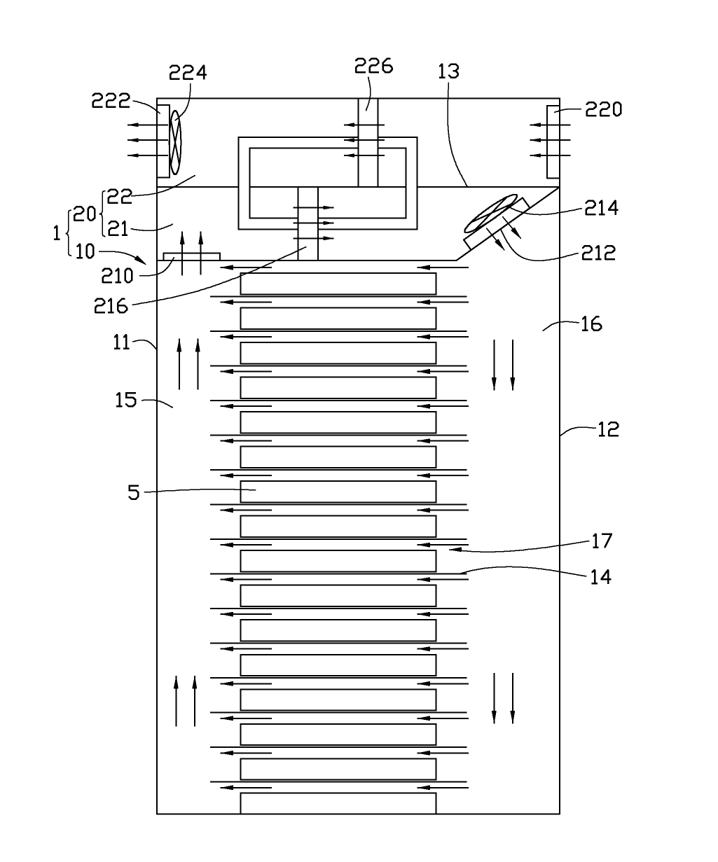

### BACKGROUND

1. Technical Field

The present disclosure relates to server systems, and more particularly, to a server system with an air cooling device.

2. Description of Related Art

In many server systems, the servers are tightly packed in a single cabinet. Each of the servers includes at least a power supply device, a motherboard, a hard disk drive, and an optical disk drive, and considerable heat is generated during operation. The servers may suffer damage if the heat is not efficiently dissipated.

What is needed, therefore, is a server system with means of overcoming the limitations as described above.

### BRIEF DESCRIPTION OF THE DRAWINGS

The components in the drawings are not necessarily drawn to scale, the emphasis instead being placed upon clearly illustrating the principles of the present disclosure.

The drawing is a schematic view of a server system according to an exemplary embodiment.

### DETAILED DESCRIPTION

Embodiments of the present disclosure are now described in detail, with reference to the accompanying drawing.

Referring to the drawing, a server system 1 according to an exemplary embodiment is illustrated. The server system 1 includes a rack 10 including a number of support plates 14 for supporting servers 5 and an air cooling device 20 for dissipating heat generated by the servers 5.

The server cabinet 10 includes a rear panel 11, a front panel 12 opposite the rear panel 11, and a top panel 13 connected between the rear panel 11 and the front panel 12. The support panels 14 are arranged in a row and divide the server cabinet 10 into a first chamber 15 adjacent to the rear panel 11 and a second chamber 16 adjacent to the front panel 12. A gap 17 exists between each two adjacent racks 14, and the gaps 17 communicate with the first chamber 15 and the second chamber 16.

The air cooling device 20 includes a first unit 21 coupled to a lower side of the top panel 13 of the rack 10 and a second unit 22 coupled to an upper side of the top panel 13. The first unit 21 includes a first inlet 210 communicating with the first chamber 15, a first outlet 212 communicating with the second chamber 16, a first fan 214, and an evaporator 216. The first fan 214 is coupled to the first inlet 210 or the first outlet 212 for accelerating airflow in the first unit 10.

The second unit 22 is stacked on top of the first unit 21 and includes a second inlet 220, a second outlet 222, and a second fan 224, and an condenser 226. In the embodiment, the second inlet 220 and the second outlet 222 are positioned at two opposite sides of the second unit 22. The second fan 224 is coupled to the second inlet 220 or to the second outlet 222 for accelerating airflow in the second unit 20.

The condenser 226 is connected to the evaporator 216 with pipes (not labeled) for providing liquid refrigerant to the evaporator 216. The evaporator 216 evaporates the liquid refrigerant and so cools air taken in from the first chamber 15 via the first inlet 210, and outputs the cooled air into the second chamber 16 via the first outlet 212. The cooled air in the second chamber 16 may flow back to the first chamber 15 via the gaps 17, thereby efficiently dissipating all the heat generated by the servers 5. The condenser 226 condenses the gaseous refrigerant from the evaporator 216 into liquid again. Air taken in from the second inlet 220 absorbs heat from the condenser 226, and flows out of the second unit 22 via the second outlet 222.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. A server system comprising:
a rack comprising:
a plurality of support plate dividing the rack into a first chamber and a second chamber, a gap existing between each two adjacent support plates and communicating with the first chamber and the second chamber; and
an air cooling device comprising a first unit defining a first inlet communicating with the first chamber and a first outlet communicating with the second chamber, and to cool the air inhaled from the first chamber via the first inlet, and to exhale the cooled air into the second chamber via the first outlet.

2. The server system as described in claim 1, wherein the first unit comprises an evaporator configured to evaporate a liquid refrigerant to cool the air taken in from the first chamber via the first inlet.

3. The server system as described in claim 2, wherein the first unit comprises a first fan coupled to the first inlet or to the first outlet to accelerate airflow in the server cabinet.

4. The server system as described in claim 2, wherein the server cabinet comprises a top panel, and the first unit of the air cooling device is coupled to a lower side of the top panel.

5. The server system as described in claim 4, wherein the air cooling device comprises a second unit coupled to an upper side of the top wall, and the second unit comprises a condenser for providing the liquid refrigerant to the evaporator.

6. The server system as described in claim 5, wherein the condenser is configured to condense the refrigerant from the evaporator.

7. The server system as described in claim 6, wherein the second unit defines a second inlet and a second outlet positioned at opposite sides thereof, and air taken in from the second inlet absorbs heat from the condenser and flows out of the second unit via the second outlet.

8. The server system as described in claim 7, wherein the second unit further comprises a second fan coupled to the second inlet or to the second outlet.
